(19) United States
(12) Patent Application Publication
(10) Pub. No.: US 2012/0032692 A1
(43) Pub. Date: Feb. 9, 2012

(54) MEMS GAS SENSOR

(75) Inventors: Manish Kothari, Cupertino, CA (US); Alok Govil, Santa Clara, CA (US)

(73) Assignee: QUALCOMM MEMS Technologies, Inc., San Diego, CA (US)

(21) Appl. No.: 12/853,094

(22) Filed: Aug. 9, 2010

(51) Int. Cl. G01R 27/26; G06F 15/00

(52) U.S. Cl. 324/672; 345/501

(57) ABSTRACT

Systems and methods for sensing a chemical or gas species of interest are provided. In one aspect, a method of sensing a chemical includes determining a capacitance change between at least two layers in a MEMS device, the capacitance between the at least two layers indicative of a presence of one or more chemicals; and identifying the presence of the one or more chemicals based on a determined electrical response of the at least two layers and the determined capacitance change.

### TECHNICAL FIELD

The present disclosure relates to electromechanical systems (MEMS).

### DESCRIPTION OF THE RELATED ART

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator. As used herein, the term interferometric modulator or interferometric light modulator refers to a device that selectively absorbs and/or reflects light using the principles of optical interference. In certain embodiments, an interferometric modulator may include a pair of conductive plates, one or both of which may be transparent and/or reflective, wholly or in part, and capable of relative motion upon application of an appropriate electrical signal. In an embodiment, one plate may include a stationary layer deposited on a substrate and the other plate may include a metallic membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

### SUMMARY

The systems, methods and devices of the present disclosure each have several innovative aspects, no single one of which is solely responsible for the desirable attributes disclosed herein.

One innovative aspect of the subject matter described in this disclosure can be implemented in a method for sensing a chemical. The method includes determining a capacitance change between at least two layers in a MEMS device, the capacitance between the at least two layers indicative of a presence of one or more chemicals; and identifying the presence of the one or more chemicals based on a determined electrical response of the at least two layers and the determined capacitance change. In one aspect, determining a capacitance change includes determining an actuation time of the MEMS device in response to a selected voltage. Determining an actuation time can include electronically measuring a change in current, or optically measuring a change in a gap distance between the at least two layers. Optically measuring a change in the gap distance can include detecting a change in the color of light emitted by the MEMS device. In another aspect, determining a capacitance change includes determining the voltage required to collapse the MEMS device. In yet another aspect, determining a capacitance change includes determining a time to open a gate of a field effect transistor.

The change in capacitance between the at least two layers can be a function of a change in residual stress in a sensing layer in the MEMS device. The change in residual stress of the sensing layer can be a function of the presence of the one or more chemicals.

A sensor is provided in another implementation. The sensor includes a movable layer configured to react to at least one chemical; and a second layer spaced from the movable layer. A change in capacitance between the movable layer and the second layer and a determined electrical response resulting from the change in capacitance are indicative of the presence of the at least one chemical. A distance between the movable layer and the second layer can be a function of the presence of the at least one chemical in one aspect. In another aspect, a distance between the movable layer and the second layer can be a function of a voltage applied between the movable layer and the second layer.

The movable layer can include a sensing layer that has a residual stress that is a function of the presence of the at least one chemical. The sensing layer can include a metal oxide. The movable layer can also include a heating layer configured to heat the sensing layer. The heating layer can include indium tin oxide. The movable layer can include aluminum or platinum.

The change in capacitance between the movable layer and the second layer may be reversible in one implementation. In another impelementation, the sensor includes a substrate spaced from the second layer. The second layer can be disposed between the substrate and the movable layer. The substrate can include glass. In some aspects, the sensor includes an interferometric modulator.

A sensor that includes means for sensing at least one chemical is provided in yet another implementation. The sensor also includes a layer spaced from the sensing means. A change in capacitance between the sensing means and the layer and a determined electrical response resulting from the change in capacitance can be indicative of the presence of the at least one chemical. In one aspect, the sensing means includes a movable layer configured to react to at least one chemical. In another aspect, the sensor includes means for interferometrically modulating light.

Note that the relative dimensions of the following figures may not be to scale.

### BRIEF DESCRIPTION OF THE DRAWINGS

FIG. 1 is an isometric view depicting a portion of one embodiment of an interferometric modulator display in which a movable reflective layer of a first interferometric modulator is in a relaxed position and a movable reflective layer of a second interferometric modulator is in an actuated position.

FIG. 2 is a system block diagram illustrating one embodiment of an electronic device incorporating a 3×3 interferometric modulator display.

FIG. 3 is a diagram of movable mirror position versus applied voltage for one exemplary embodiment of an interferometric modulator of FIG. 1.

FIG. 4 is an illustration of a set of row and column voltages that may be used to drive an interferometric modulator display.

FIGS. 5A and 5B illustrate one exemplary timing diagram for row and column signals that may be used to write a frame of display data to the 3×3 interferometric modulator display of FIG. 2.

FIGS. 6A and 6B are system block diagrams illustrating an embodiment of a visual display device comprising a plurality of interferometric modulators.

FIG. 7A is a cross section of one embodiment of a MEMS gas sensor.

FIG. 7B is a top view of the gas sensor of FIG. 7A.

FIG. 8 is a top view of the MEMS gas sensor of FIG. 7A illustrating a heating layer.

FIG. 9 is a top view of an alternative embodiment of a MEMS gas sensor.

FIG. 10 is an equivalent circuit of the MEMS gas sensor of FIG. 7A.

FIG. 11 is a flowchart illustrating one method for identifying the presence of a gas species of interest in the MEMS gas sensor of FIG. 7A.

FIG. 12 is a cross section of the MEMS gas sensor of FIG. 7A connected to a field effect transistor.

FIG. 13 is a flowchart illustrating one method of identifying the presence of a gas species of interest using the field effect transistor of FIG. 12.

FIG. 14 is a cross section of the MEMS gas sensor of FIG. 7A connected to an ammeter.

FIG. 15 is a flowchart illustrating one method of identifying the presence of a gas species of interest using the ammeter of FIG. 14 or a spectrometer.

### DETAILED DESCRIPTION

The following detailed description is directed to certain specific embodiments. However, the teachings herein can be applied in a multitude of different ways. In this description, like reference numbers and designations in the various drawings indicate like elements. The embodiments may be implemented in any device that is configured to display an image, whether in motion (e.g., video) or stationary (e.g., still image), and whether textual or pictorial. More particularly, it is contemplated that the embodiments may be implemented in or associated with a variety of electronic devices such as, but not limited to, mobile telephones, multimedia Internet enabled cellular telephones, mobile television receivers, wireless devices, personal data assistants (PDAs), wireless electronic mail receivers, hand-held or portable computers, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, packaging, and aesthetic structures (e.g., display of images on a piece of jewelry). MEMS devices of similar structure to those described herein can also be used in non-display applications such as in electronic switching devices.

Methods and systems for sensing a chemical are provided herein. For example, embodiments of gas sensors described herein can detect toxic pollutants and inflammable gases. In one implementation, a method of sensing a chemical includes determining a capacitance change between at least two layers in a MEMS device, the capacitance between the at least two layers indicative of a presence of one or more chemicals. The method also includes identifying the presence of the one or more chemicals based on a determined electrical response of the at least two layers and the determined capacitance change.

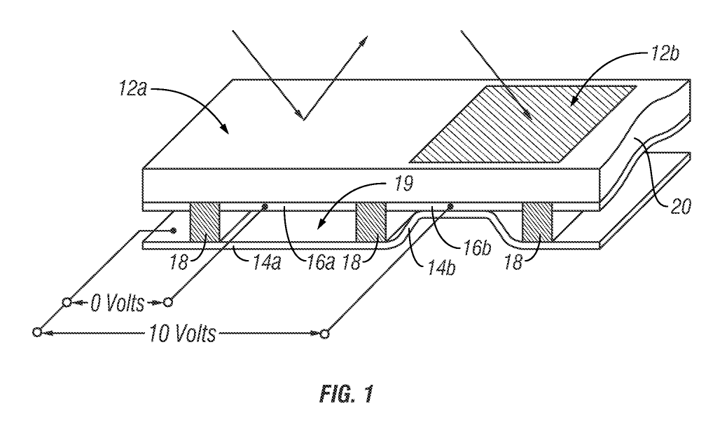

One interferometric modulator display device comprising an interferometric MEMS display element is illustrated in FIG. 1. In these devices, the pixels of the MEMS display element are in either a bright or dark state. In the bright (“relaxed” or “open”) state, the display element reflects a large portion of incident visible light to a user. Conversely, in the dark (“actuated” or “closed”) state, the display element reflects little incident visible light. In some implementations, the light reflectance properties of the “on” and “off” states may be reversed. MEMS pixels can be configured to reflect predominantly at particular wavelengths allowing for a color display in addition to black and white.

FIG. 1 is an isometric view depicting two adjacent pixels in a series of pixels of a visual display, wherein each pixel includes a MEMS interferometric modulator. In some embodiments, an interferometric modulator display comprises a row/column array of these interferometric modulators. Each interferometric modulator includes a pair of reflective layers positioned at a variable and controllable distance from each other to form a resonant optical gap with at least one variable dimension. In one embodiment, one of the reflective layers may be moved between two positions. In the first position, referred to herein as the relaxed position, the movable reflective layer is positioned at a relatively large distance from a fixed partially reflective layer. In the second position, referred to herein as the actuated position, the movable reflective layer is positioned more closely adjacent to the partially reflective layer. Incident light that reflects from the two layers interferes constructively or destructively depending on the position of the movable reflective layer, producing either an overall reflective or non-reflective state for each pixel.

The depicted portion of the pixel array in FIG. 1 includes two adjacent interferometric modulators 12a and 12b. In the interferometric modulator 12a on the left, a movable reflective layer 14a is illustrated in a relaxed position at a predetermined distance from an optical stack 16a, which includes a partially reflective layer. In the interferometric modulator 12b on the right, the movable reflective layer 14b is illustrated in an actuated position adjacent to the optical stack 16b.

The optical stacks 16a and 16b (collectively referred to as optical stack 16), as referenced herein, typically include several fused layers, which can include an electrode layer, such as indium tin oxide (ITO), a partially reflective layer, such as chromium, and a transparent dielectric. The optical stack 16 is thus electrically conductive, partially transparent and partially reflective, and may be fabricated, for example, by depositing one or more of the above layers onto a transparent substrate 20. The partially reflective layer can be formed from a variety of materials that are partially reflective such as various metals, semiconductors, and dielectrics. The partially reflective layer can be formed of one or more layers of materials, and each of the layers can be formed of a single material or a combination of materials.

In some embodiments, the layers of the optical stack 16 are patterned into parallel strips, and may form row electrodes in a display device as described further below. The movable reflective layers 14a, 14b may be formed as a series of parallel strips of a deposited metal layer or layers (orthogonal to the row electrodes of 16a, 16b) to form columns deposited on top of posts 18 and an intervening sacrificial material deposited between the posts 18. When the sacrificial material is etched away, the movable reflective layers 14a, 14b are separated from the optical stacks 16a, 16b by a defined gap 19, or cavity. A highly conductive and reflective material such as aluminum may be used for the reflective layers 14, and these strips may form column electrodes in a display device. Note that FIG. 1 may not be drawn to scale. For example, in some implementations, the spacing between posts 18 may be on the order of 10-100 um, while the gap 19 may be on the order of <1000 Angstroms (Å).

With no applied voltage, the gap 19 remains between the movable reflective layer 14a and optical stack 16a, with the movable reflective layer 14a in a mechanically relaxed state, as illustrated by the pixel 12a in FIG. 1. However, when a potential (voltage) difference is applied to a selected row and column, the capacitor formed at the intersection of the row and column electrodes at the corresponding pixel becomes charged, and electrostatic forces pull the electrodes together. If the voltage is high enough, the movable reflective layer 14b is deformed and is forced against the optical stack 16b. A dielectric layer (not illustrated in this Figure) within the optical stack 16b may prevent shorting and control the separation distance between layers 14b and 16b, as illustrated by actuated pixel 12b on the right in FIG. 1. The behavior is the same regardless of the polarity of the applied potential difference.

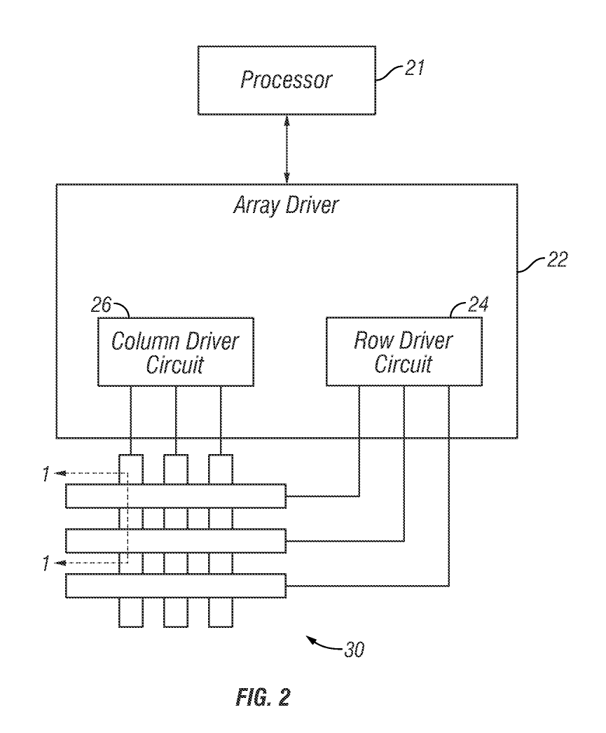

FIGS. 2-5 illustrate one exemplary process and system for using an array of interferometric modulators in a display application.

FIG. 2 is a system block diagram illustrating one embodiment of an electronic device that may incorporate interferometric modulators. The electronic device includes a processor 21 which may be any general purpose single- or multi-chip microprocessor such as an ARM®, Pentium®, 8051, MIPS®, Power PC®, or ALPHA®, or any special purpose microprocessor such as a digital signal processor, microcontroller, or a programmable gate array. As is conventional in the art, the processor 21 may be configured to execute one or more software modules. In addition to executing an operating system, the processor may be configured to execute one or more software applications, including a web browser, a telephone application, an email program, or any other software application.

In one embodiment, the processor 21 is also configured to communicate with an array driver 22. In one embodiment, the array driver 22 includes a row driver circuit 24 and a column driver circuit 26 that provide signals to a display array or panel 30. The cross section of the array illustrated in FIG. 1 is shown by the lines 1-1 in FIG. 2. Note that although FIG. 2 illustrates a 3×3 array of interferometric modulators for the sake of clarity, the display array 30 may contain a very large number of interferometric modulators, and may have a different number of interferometric modulators in rows than in columns (e.g., 300 pixels per row by 190 pixels per column).

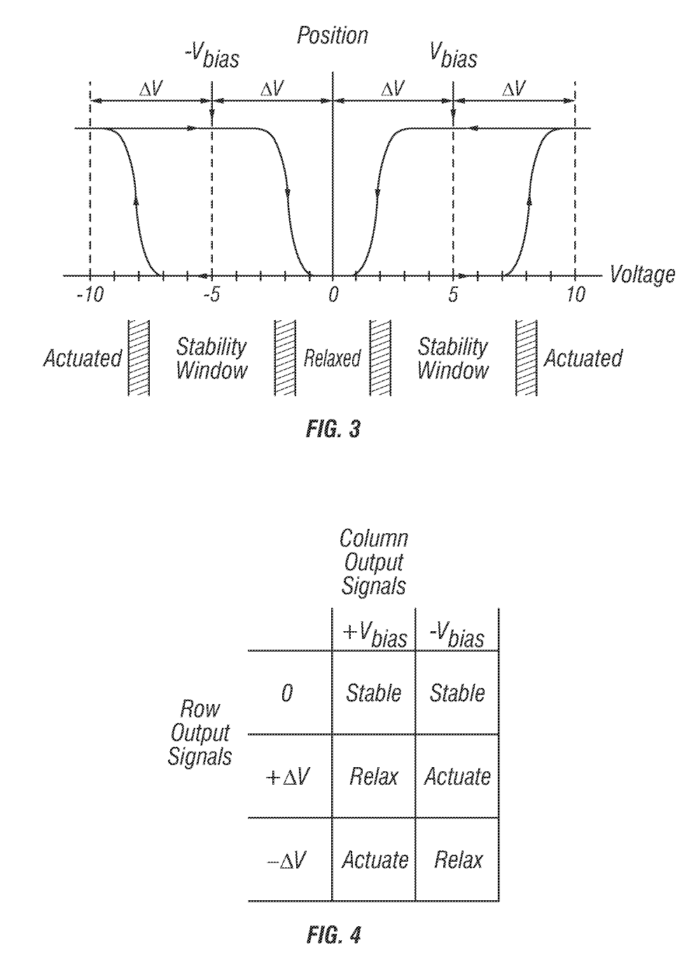

FIG. 3 is a diagram of movable mirror position versus applied voltage for one exemplary embodiment of an interferometric modulator of FIG. 1. For MEMS interferometric modulators, the row/column actuation protocol may take advantage of a hysteresis property of these devices as illustrated in FIG. 3. An interferometric modulator may require, for example, about a 10-volt potential difference to cause a movable layer to change from the relaxed state to the actuated state. However, when the voltage is reduced from that value, the movable layer maintains its state as the voltage drops back below 10-volts. In the exemplary embodiment of FIG. 3, the movable layer does not relax completely until the voltage drops below 2-volts. Thus, a range of voltage, approximately 3 to 7-volts in the example illustrated in FIG. 3, exists where there is a window of applied voltage within which the device is stable in either the relaxed or actuated state. This is referred to herein as the “hysteresis window” or “stability window.” For a display array having the hysteresis characteristics of FIG. 3, the row/column actuation protocol can be designed such that during row strobing, pixels in the strobed row that are to be actuated are exposed to a voltage difference of about 10-volts, and pixels that are to be relaxed are exposed to a voltage difference of near zero volts. After strobing, the pixels are exposed to a steady state or bias voltage difference of approximately 5-volts such that they remain in the previous strobing state. In this example, after being written, each pixel sees a potential difference within the “stability window” of about 3-7-volts. This feature makes the pixel design illustrated in FIG. 1 stable under the same applied voltage conditions in either an actuated or relaxed pre-existing state. Since each pixel of the interferometric modulator, whether in the actuated or relaxed state, is essentially a capacitor formed by the fixed and moving reflective layers, this stable state can be held at a steady voltage within the hysteresis window without consuming or losing power. Essentially no current flows into the pixel if the applied voltage potential remains fixed.

In some implementations, a frame of an image may be created by sending a set of data signals (each having a certain voltage level) across the set of column electrodes in accordance with the desired set of actuated pixels in the first row. A row pulse is then applied to a first row electrode, actuating the pixels corresponding to the set of data signals. The set of data signals is then changed to correspond to the desired set of actuated pixels in a second row. A pulse is then applied to the second row electrode, actuating the appropriate pixels in the second row in accordance with the data signals. The first row of pixels are unaffected by the second row pulse, and remain in the state they were set to during the first row pulse. This may be repeated for the entire series of rows in a sequential fashion to produce the frame. Generally, the frames are refreshed and/or updated with new image data by continually repeating this process at some desired number of frames per second. A wide variety of protocols for driving row and column electrodes of pixel arrays to produce image frames may be used.

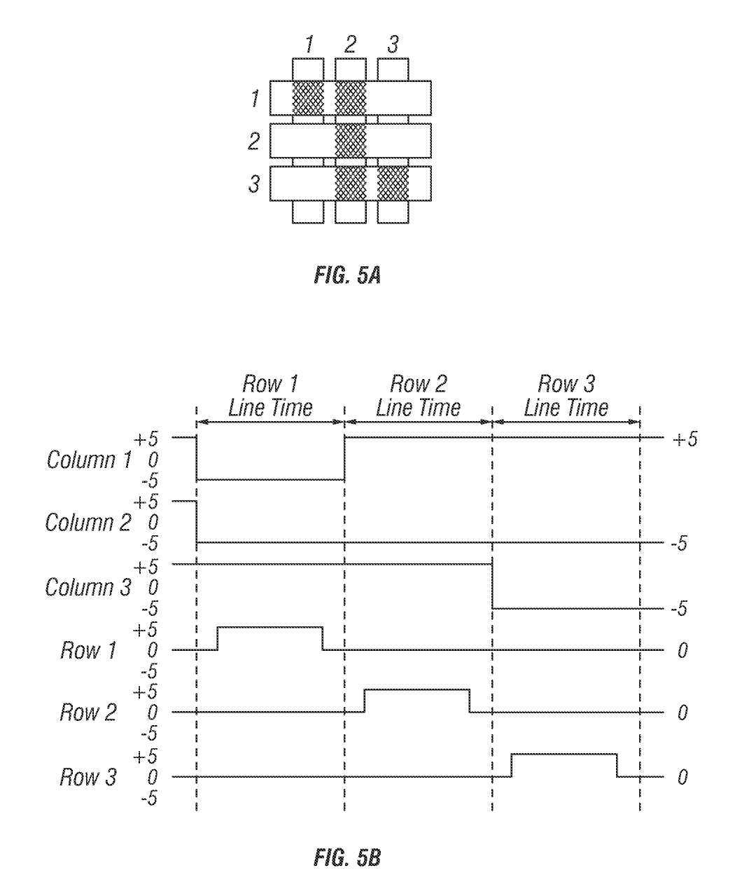

FIGS. 4 and 5 illustrate one possible actuation protocol for creating a display frame on the 3×3 array of FIG. 2. FIG. 4 illustrates a possible set of column and row voltage levels that may be used for pixels exhibiting the hysteresis curves of FIG. 3. In the FIG. 4 embodiment, actuating a pixel involves setting the appropriate column to −V_{bias}, and the appropriate row to +ΔV, which may correspond to −5-volts and +5-volts respectively Relaxing the pixel is accomplished by setting the appropriate column to +V_{bias}, and the appropriate row to the same +ΔV, producing a zero volt potential difference across the pixel. In those rows where the row voltage is held at zero volts, the pixels are stable in whatever state they were originally in, regardless of whether the column is at +V_{bias}, or −V_{bias}. As is also illustrated in FIG. 4, voltages of opposite polarity than those described above can be used, e.g., actuating a pixel can involve setting the appropriate column to +V_{bias}, and the appropriate row to −ΔV. In this embodiment, releasing the pixel is accomplished by setting the appropriate column to −V_{bias}, and the appropriate row to the same −ΔV, producing a zero volt potential difference across the pixel.

FIG. 5B is a timing diagram showing a series of row and column signals applied to the 3×3 array of FIG. 2 which will result in the display arrangement illustrated in FIG. 5A, where actuated pixels are non-reflective. Prior to writing the frame illustrated in FIG. 5A, the pixels can be in any state, and in this example, all the rows are initially at zero volts, and all the columns are at +5-volts. With these applied voltages, all pixels are stable in their existing actuated or relaxed states.

In the FIG. 5A frame, pixels (1,1), (1,2), (2,2), (3,2) and (3,3) are actuated. To accomplish this, during a “line time” for row 1, columns 1 and 2 are set to −5-volts, and column 3 is set to +5-volts. This does not change the state of any pixels, because all the pixels remain in the 3-7-volt stability window. Row 1 is then strobed with a pulse that goes from 0, up to 5-volts, and back to zero. This actuates the (1,1) and (1,2) pixels and relaxes the (1,3) pixel. No other pixels in the array are affected. To set row 2 as desired, column 2 is set to −5-volts, and columns 1 and 3 are set to +5-volts. The same strobe applied to row 2 will then actuate pixel (2,2) and relax pixels (2,1) and (2,3). Again, no other pixels of the array are affected. Row 3 is similarly set by setting columns 2 and 3 to −5-volts, and column 1 to +5-volts. The row 3 strobe sets the row 3 pixels as shown in FIG. 5A. After writing the frame, the row potentials are zero, and the column potentials can remain at either +5 or −5-volts, and the display is then stable in the arrangement of FIG. 5A. The same procedure can be employed for arrays of dozens or hundreds of rows and columns. The timing, sequence, and levels of voltages used to perform row and column actuation can be varied widely within the general principles outlined above, and the above example is exemplary only, and any actuation voltage method can be used with the systems and methods described herein.

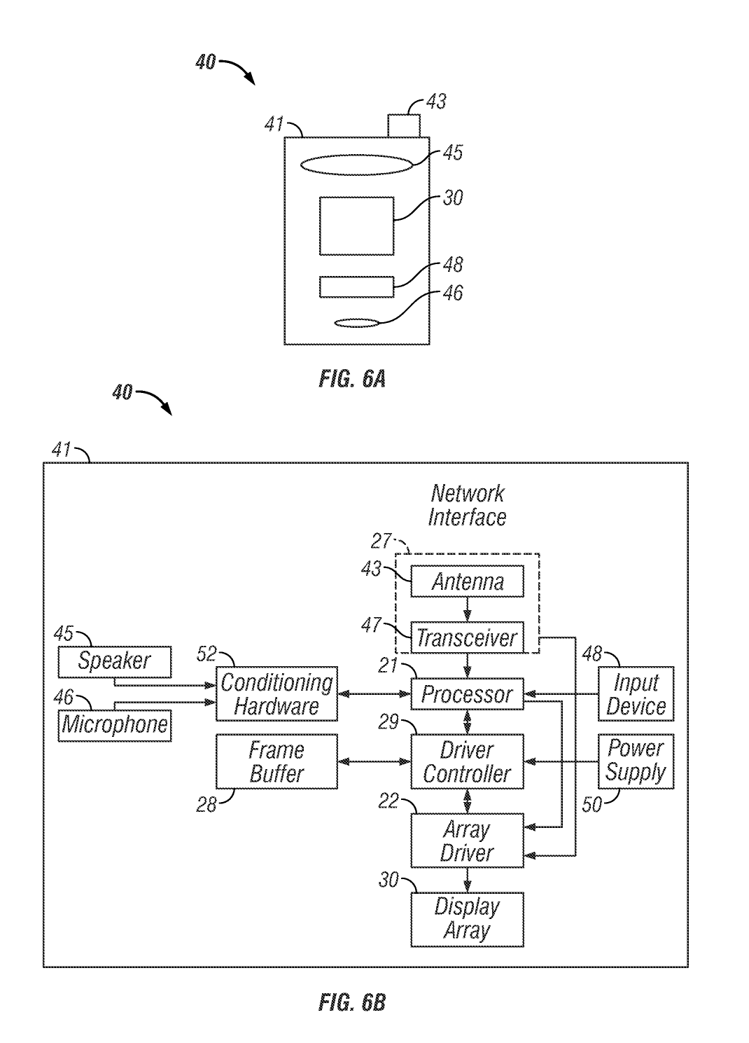

FIGS. 6A and 6B are system block diagrams illustrating an embodiment of a display device 40. The display device 40 can be, for example, a cellular or mobile telephone. However, the same components of display device 40 or slight variations thereof are also illustrative of various types of display devices such as televisions, e-readers, and portable media players.

The display device 40 includes a housing 41, a display 30, an antenna 43, a speaker 45, an input device 48, and a microphone 46. The housing 41 is generally formed from any of a variety of manufacturing processes, including injection molding, and vacuum forming. In addition, the housing 41 may be made from any of a variety of materials, including but not limited to plastic, metal, glass, rubber, and ceramic, or a combination thereof. In one embodiment the housing 41 includes removable portions (not shown) that may be interchanged with other removable portions of different color, or containing different logos, pictures, or symbols.

The display 30 may be any of a variety of displays, including a bi-stable display, as described herein. In other embodiments, the display 30 can include a flat-panel display, such as plasma, EL, OLED, STN LCD, or TFT LCD, or a non-flat-panel display, such as a CRT or other tube device. In addition, the display 30 can include an interferometric modulator display, as described herein.

The components of one embodiment of the exemplary display device 40 are schematically illustrated in FIG. 6B. The illustrated exemplary display device 40 includes a housing 41 and can include additional components at least partially enclosed therein. For example, in one embodiment, the exemplary display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 provides power to all components as required by the particular exemplary display device 40 design.

The network interface 27 includes the antenna 43 and the transceiver 47 so that the exemplary display device 40 can communicate with one or more devices over a network. In one embodiment the network interface 27 may also have some processing capabilities to relieve requirements of the processor 21. The antenna 43 can transmit and receive signals. In one embodiment, the antenna 43 transmits and receives RF signals according to the IEEE 802.11 standard, including IEEE 802.11(a), (b), or (g). In another embodiment, the antenna 43 transmits and receives RF signals according to the BLUETOOTH standard. In the case of a cellular telephone, the antenna 43 is designed to receive CDMA, GSM, AMPS, W-CDMA, or other known signals that are used to communicate within a wireless cell phone network. The transceiver 47 pre-processes the signals received from the antenna 43 so that they may be received by and further manipulated by the processor 21. The transceiver 47 also processes signals received from the processor 21 so that they may be transmitted from the exemplary display device 40 via the antenna 43.

In an alternative embodiment, the transceiver 47 can be replaced by a receiver. In yet another alternative embodiment, network interface 27 can be replaced by an image source, which can store or generate image data to be sent to the processor 21. For example, the image source can be a digital video disc (DVD) or a hard-disc drive that contains image data, or a software module that generates image data.

Processor 21 generally controls the overall operation of the exemplary display device 40. The processor 21 receives data, such as compressed image data from the network interface 27 or an image source, and processes the data into raw image data or into a format that is readily processed into raw image data. The processor 21 then sends the processed data to the driver controller 29 or to frame buffer 28 for storage. Raw data typically refers to the information that identifies the image characteristics at each location within an image. For example, such image characteristics can include color, saturation, and gray-scale level.

In one embodiment, the processor 21 includes a microcontroller, CPU, or logic unit to control operation of the exemplary display device 40. Conditioning hardware 52 may include amplifiers and filters for transmitting signals to the speaker 45, and for receiving signals from the microphone 46. Conditioning hardware 52 may be discrete components within the exemplary display device 40, or may be incorporated within the processor 21 or other components.

The driver controller 29 takes the raw image data generated by the processor 21 either directly from the processor 21 or from the frame buffer 28 and re-formats the raw image data appropriately for high speed transmission to the array driver 22. Specifically, the driver controller 29 re-formats the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. They may be embedded in the processor 21 as hardware, embedded in the processor 21 as software, or fully integrated in hardware with the array driver 22.

Typically, the array driver 22 receives the formatted information from the driver controller 29 and re-formats the video data into a parallel set of waveforms that are applied many times per second to the hundreds and sometimes thousands of leads coming from the display's x-y matrix of pixels.

In some implementations, the driver controller 29, array driver 22, and display array 30 are appropriate for any of the types of displays described herein. For example, in one embodiment, driver controller 29 is a conventional display controller or a bi-stable display controller (e.g., an interferometric modulator controller). In another embodiment, array driver 22 is a conventional driver or a bi-stable display driver (e.g., an interferometric modulator display). In some implementations, the driver controller 29 can be integrated with the array driver 22. Such an implementation is common in highly integrated systems such as cellular phones, watches and other small-area displays. In yet another embodiment, display array 30 is a typical display array or a bi-stable display array (e.g., a display including an array of interferometric modulators).

The input device 48 allows a user to control the operation of the exemplary display device 40. In one embodiment, input device 48 includes a keypad, such as a QWERTY keyboard or a telephone keypad, a button, a switch, a rocker, a touch-sensitive screen, or a pressure- or heat-sensitive membrane. In one embodiment, the microphone 46 is an input device for the exemplary display device 40. When the microphone 46 is used to input data to the device, voice commands can be used for controlling operations of the exemplary display device 40.

Power supply 50 can include a variety of energy storage devices as are well known in the art. For example, in one embodiment, power supply 50 is a rechargeable battery, such as a nickel-cadmium battery or a lithium-ion battery. In another embodiment, power supply 50 is a renewable energy source, a capacitor, or a solar cell, including a plastic solar cell and solar-cell paint. The power supply 50 also can be configured to receive power from a wall outlet.

In some implementations, control programmability resides, as described above, in a driver controller 29 which can be located in several places in the electronic display system. In some cases, control programmability resides in the array driver 22. The above-described optimization may be implemented in any number of hardware and/or software components and in various configurations.

### MEMS Gas Sensor

Methods and systems to detect a chemical or gas species of interest using a MEMS gas sensor are provided herein. For example, embodiments of MEMS gas sensors described herein can use a change in capacitance between two or more layers of a MEMS device to detect toxic pollutants and inflammable gases. Examples of chemicals and gases which can be detected include but are not limited to NO₂, NO, SOₓ, CO₂, and O₃.

Without being bound by any particular theory, changes in capacitance between layers in MEMS devices described herein can be caused by adsorption of gas molecules on the surface of a sensing layer in the MEMS device. The sensitivity of the sensing layer to gas molecules can be a function of temperature. In some embodiments, the sensing layer is activated by heat, bringing the sensor to a required temperature range for detection of a particular gas species. A typical temperature range to activate sensing layers described herein is approximately 200 to 500° C.

Embodiments of MEMS gas sensors described herein can be advantageously constructed on non-silicon substrates, function over a wide range of resistances while also supporting large resistance variations, and can be incorporated into a variety of displays, including but not limited to interferometric modulator, OLED, and LCD displays.

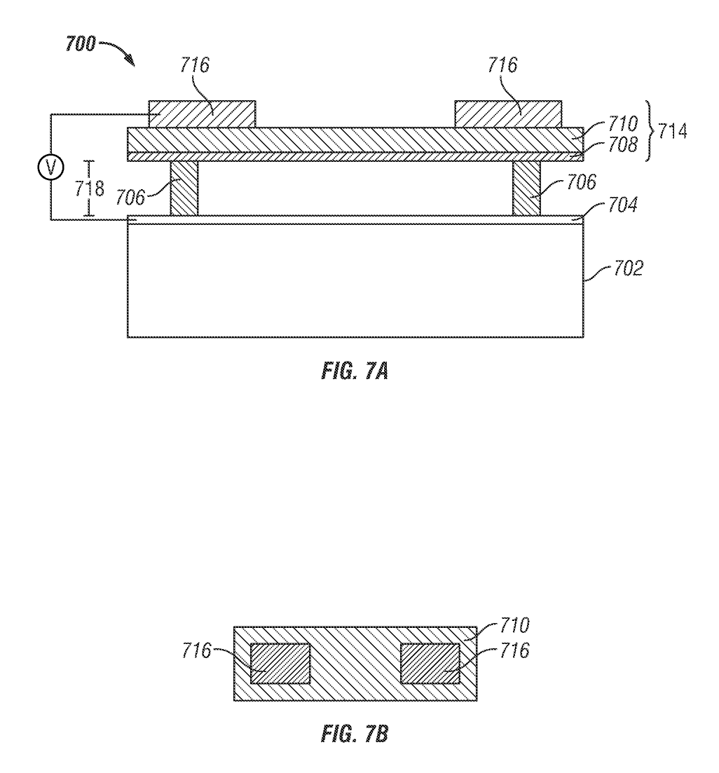

FIG. 7A is a cross section of one embodiment of a MEMS gas sensor 700 that can sense the presence of a gas species of interest. FIG. 7B is a top view of the exemplary gas sensor 700. The MEMS gas sensor 700 includes a substrate 702 which may comprise a variety of materials, for example glass or plastic materials. For example, in one embodiment, the substrate 702 comprises glass. In another embodiment, the substrate 702 comprises plastic. In yet another embodiment, the substrate 702 comprises silicon. The substrate is transparent or substantially transparent in some aspects.

The MEMS gas sensor 700 comprises an absorber/insulator layer 704 (hereinafter referred to as absorber layer 704) disposed over the substrate 702. The absorber layer 704 can comprise any suitable material, for example molybdenum, chrome, tungsten, tantalum, silicon, titanium, or molychrome. In some embodiments, the absorber layer 704 comprises an optical oxide. For example, the absorber layer 704 can comprise SiO, SiN, AlO, SiNi, or SiON. The absorber layer 704 can be electrically conductive in some aspects. For example, embodiments of the absorber layer 704 described herein can comprise an electrode layer such as that described above with reference to optical stacks 16a, 16b in FIG. 1. The MEMS gas sensor 700 also includes a plurality of supports 706 disposed over the substrate 702. In some aspects, the supports 706 comprise a dielectric material.

The MEMS gas sensor 700 also includes a sensing layer 710 disposed over the supports 706. Embodiments of the sensing layer 710 can comprise any suitable material, for example a metal oxide. The sensing layer 710 can comprise, for example, tin oxide, tungsten oxide, indium tin oxide, nitrogen oxide, zinc oxide, or any other suitable metal oxide. In some aspects, the material of the sensing layer 710 is chosen based on the particular gas species of interest the MEMS gas sensor 700 is expected to detect.

The MEMS gas sensor 700 can optionally comprise a heating layer 708 disposed over the supports 706. As shown in FIG. 7A, the heating layer 708 is disposed between the sensing layer 710 and the supports 706 in some embodiments. The heating layer 708 is also reflective in some aspects. For example, embodiments of the heating layer 708 can comprise a reflective layer such as that described above with reference to movable reflective layers 14a, 14b in FIG. 1. The heating layer 708 can comprise a material with high resistivity. For example, the heating layer 708 comprises a metal in some aspects. In one embodiment, the heating layer 708 comprises aluminum. In another embodiment, the heating layer 708 comprises indium tin oxide (ITO).

The MEMS gas sensor 700 also includes one or more electrodes 716 disposed on the sensing layer 710. The electrodes 716 can comprise a metal, for example aluminum or platinum. The heating layer 708, the sensing layer 710, and the electrodes 716 can together form a movable element 714.

The gas sensor 700 is actuatable from a relaxed state shown in FIG. 7A and an actuated state (not shown) by moving the movable element 714 in a direction generally perpendicular to the substrate 702. In certain embodiments, the actuation of the gas sensor 700 occurs in response to a voltage difference applied between the absorber layer 704 and the electrodes 716. In some aspects, selectively moving the movable element 714 with respect to the substrate 702, for example from the relaxed state illustrated in FIG. 7A to an actuated state described with reference to FIG. 1, modulates one or more properties of light emitted from the gas sensor 700.

Embodiments of the MEMS gas sensor 700 can form an actuatable element, for example a pixel or a sub-pixel, in a variety of display systems. For example, the MEMS gas sensors described herein can be used in any display device susceptible to contamination by gases, such as OLED and LCD devices.

Referring now to FIG. 7B, the electrodes 716 can be patterned in the shape of squares or rectangles disposed on the sensing layer 710. It will be understood, however, that embodiments of the electrodes 716 are not limited to square or rectangular shapes, as discussed below with reference to FIG. 9. The electrodes 716 can be electrically connected to each other via a probe, another layer of electrically conductive material patterned or deposited over the electrodes 716, contact points on the electrodes 716, or any other suitable means. As noted above, it will also be understood that the MEMS gas sensor 700 may comprise one electrode 716 in lieu of a plurality of electrodes 716.

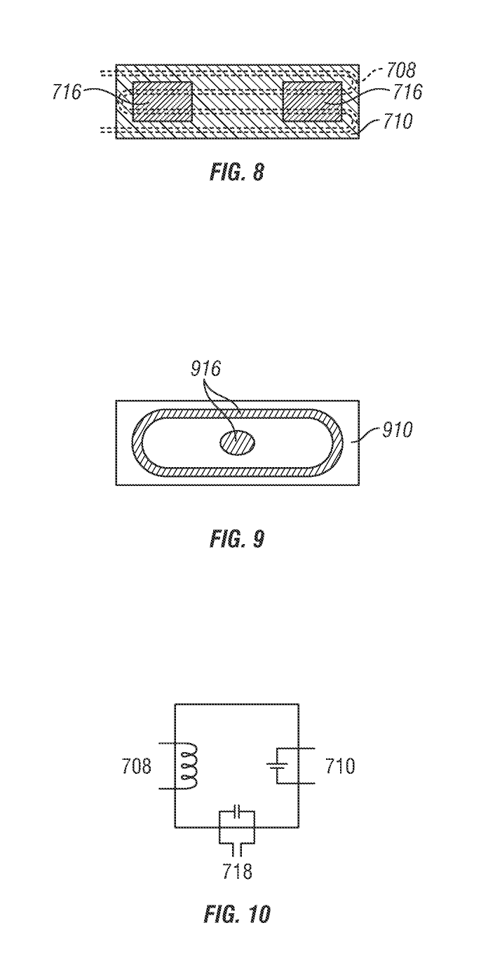

FIG. 8 is a top view of the MEMS gas sensor 700 illustrating one embodiment of the heating layer 708 in dashed lines disposed below the sensing layer 710. It will be understood that the heating layer 708 can be disposed above the sensing layer 710 and below the electrodes 716 in some embodiments. It will also be understood that embodiments of the heating layer 708 are not limited to the configuration illustrated in FIG. 9, and can comprise a layer that has the same or substantially the same surface area as the sensing layer 710. In some aspects, the heating layer 708 is a resistive heater and comprises a material having high resistivity, for example aluminum or ITO. In one embodiment, the heating layer 708 is patterned on the sensing layer 710 such that, when heated, the heating layer 708 distributes heat across the sensing layer 710.

FIG. 9 is a top view of an alternative embodiment of a MEMS gas sensor 900. The gas sensor 900 comprises electrodes 916 that are patterned in the shape of a ring and a circle. The electrodes 916 can be disposed on the sensing layer 910. Other configurations are possible. The electrodes 916 can comprise a metal, for example aluminum or platinum.

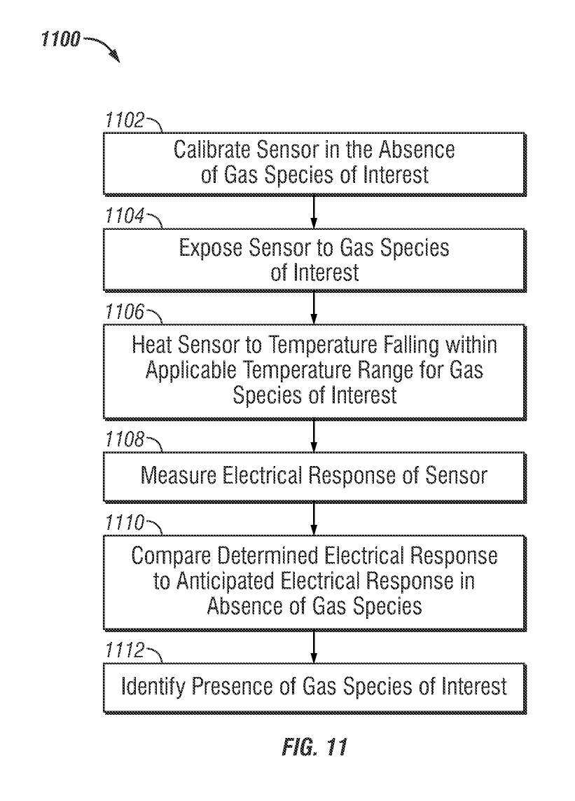

FIG. 10 is an equivalent circuit of the MEMS gas sensor 700. As described in detail above, the gas sensor 700 can include a heating layer 708 comprising a resistive heater. The heating layer 708 can comprise an ITO heating layer, for example. In one embodiment, the heating layer 708 is configured to heat the sensing layer 710 to a particular temperature for detection of a specific gas species of interest. In another embodiment, the gas sensor 700 includes a temperature sensor 718. The temperature sensor 718 can confirm that the heating layer 708 has heated the sensing layer 710 to a desired temperature and the sensing layer 710 is ready to detect the presence of a particular gas species of interest.

It will be understood, however, that some embodiments of MEMS gas sensors 700 described herein do not comprise a heating layer 708. In some embodiments, the sensing layer 710 can sense the presence of a gas species of interest at ambient temperature, and need not be heated in order to sense the presence of the gas. It will also be understood that in some embodiments (not shown), the MEMS gas sensor 700 includes a sensing layer 710 that comprises the heating layer 708. For example, in one embodiment, the sensing layer 710 comprises indium tin oxide and incorporates the heating layer 708.

### Methods of Detecting a Gas Using a MEMS Gas Sensor

As described above with reference to FIG. 7A, a voltage V can be applied between the absorber layer 704 and the electrodes 716. The presence of a gas species of interest in the device 700 can change the capacitances between at least two layers in the MEMS gas sensor 700. For example, the presence of a gas species of interest in the MEMS gas sensor 700 can change the capacitance between the absorber layer 704 and the electrodes 716, the sensing layer 710, and/or the heating layer 708. This change in capacitance between at least two layers can be detected in order to identify the presence of a gas species of interest in the MEMS gas sensor 700.

FIG. 11 is a flowchart illustrating one method 1100 for identifying the presence of a gas species of interest using the MEMS gas sensor 700. The MEMS gas sensor 700 can detect the presence of a gas species of interest when gas molecules are adsorbed by the sensing layer 710, causing a residual stress change in the sensing layer 710. The method begins at a block 1102, in which the MEMS gas sensor 700 is first calibrated before being exposed to a particular gas species. Calibration can be performed to determine the electrical response of the MEMS gas sensor 700 in the absence of the gas. In one embodiment, the calibration procedure is performed during manufacture of the MEMS gas sensor 700.

The MEMS gas sensor 700 can be calibrated using various methods. Calibration methods to determine the electrical response of the MEMS gas sensor 700 in the absence of a gas will be described in greater detail below with reference to FIGS. 13 and 15.

At a block 1104, the MEMS gas sensor 700 is exposed to a gas species of interest. In some aspects, for example, the gas sensor 700 may be exposed to a gas after manufacturing is complete and when a display device comprising the gas sensor 700 is in use.

Moving to a block 1106, the sensing layer 710 of the MEMS gas sensor 700 is heated to a temperature falling within the applicable temperature range for a particular gas species of interest. For example, the applicable temperature range to detect the presence of carbon dioxide in the MEMS gas sensor 700 may be about 400° C. to about 600° C. As described above with reference to FIGS. 8 and 10, the heating layer 708 of the MEMS gas sensor 700 can be activated in order to heat the sensing layer 710 to a temperature of, for example, 500° C. The sensing layer 710 can be heated to other temperatures as appropriate to detect a particular gas species of interest.

It will be understood that the sensing layer 710 can first be heated to a temperature falling within the applicable temperature range for a particular gas species of interest, then the MEMS gas sensor 700 can be exposed to the gas species. In some embodiments, for example, the method moves from block 1102 to block 1106, in which the sensing layer 710 is heated, then the MEMS gas sensor 700 is exposed to a gas species of interest at block 1104.

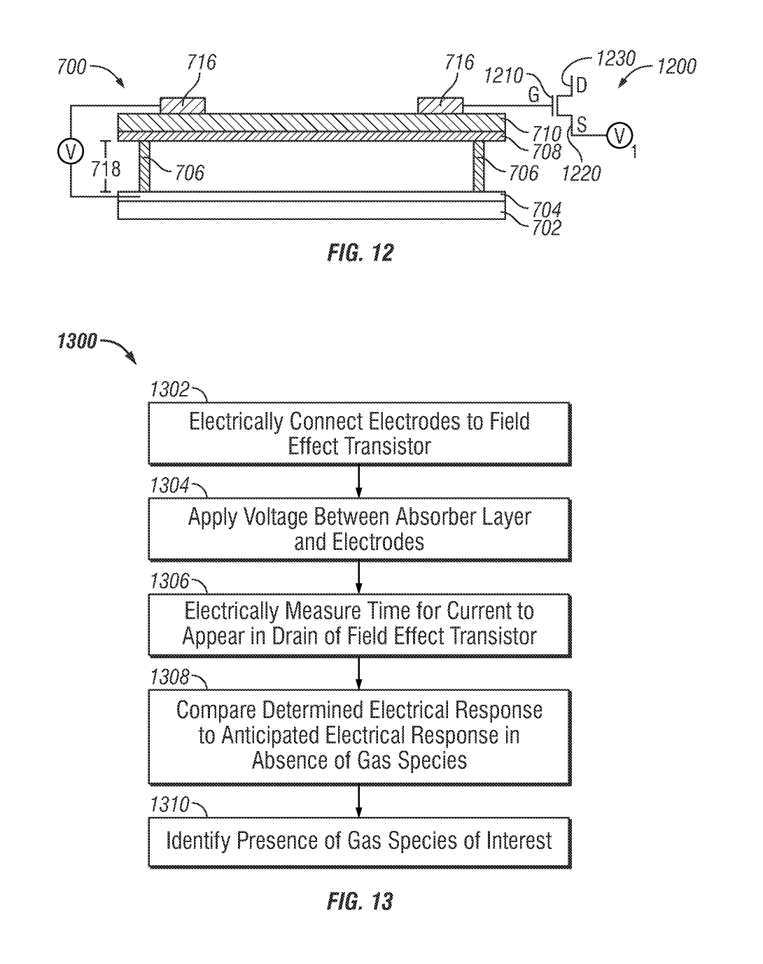

The method next moves to a block 1108, in which an electrical response of the MEMS gas sensor 700 is measured. Various methods for determining the electrical response of the MEMS gas sensor 700 are described in detail below with reference to FIGS. 12-15.

At a block 1110, the electrical response determined at block 1108 is compared to the electrical response the MEMS gas sensor 700 would be anticipated to exhibit in the absence of the gas species of interest. In one embodiment, the calibration performed at block 1102 on the MEMS gas sensor 700 provides information on the anticipated electrical response of the MEMS gas sensor 700 in the absence of the gas species of interest.

In another embodiment, the anticipated electrical response of the MEMS gas sensor 700 is determined based on known electrical and material property characteristics of MEMS gas sensors 700 at a specific temperature. For example, the electrical response of multiple MEMS gas sensors 700 operating at a particular temperature, in the absence of a gas, can be tested. The resulting test data can yield information on the anticipated electrical response of a specific MEMS gas sensor 700 operating at the given temperature in the absence of a gas.

Moving next to a block 1112, the presence of the gas species of interest is identified. In one embodiment, the difference between the electrical response of the MEMS gas sensor 700 measured or determined at block 1108 and the anticipated electrical response of the MEMS gas sensor 700 is correlated to the presence of a gas species of interest in the device 700. In another embodiment, the specific electrical response of the MEMS gas sensor 700 in the presence of a gas is used to determine the concentration of the gas species.

### Determining Capacitance Change Using a Field Effect Transistor

FIG. 12 is a cross section of the MEMS gas sensor 700 connected to a field effect transistor 1200. The field effect transistor includes a gate terminal 1210, a source terminal 1220, and a drain terminal 1230. In operation, electrons flow from the source terminal 1220 toward the drain terminal 1230 if influenced by an applied voltage V₁. The gate terminal 1210 permits electrons to flow through or blocks their passage by creating or eliminating a channel between the source terminal 1220 and the drain terminal 1230.

The sensing layer 710 can have a residual stress that is a function of the presence of a gas in the MEMS gas sensor 700. Thus, in some aspects, the presence of a gas in the MEMS gas sensor 700 causes a residual stress change in the sensing layer 710 such that the layer 710 sags slightly in a gap 718 between the absorber layer 704 and the movable element 714. As a result, in certain embodiments, the distance between the movable element 714 and the absorber layer 704 is a function of the presence of the gas in the MEMS gas sensor 700. The residual stress change of the sensing layer 710 causes a change in the capacitance between the absorber layer 704 and the electrodes 716, the capacitance between the absorber layer 704 and the heating layer 708, and/or the capacitance between the absorber layer 704 and the sensing layer 710. This change in capacitance is determined or detected as a change in the electrical response from that which would be expected from the MEMS gas sensor 700 in the absence of the gas. Specifically, the presence of the gas species of interest can cause a change in the time it takes for an electrical event to occur in the field effect transistor 1200, and this change in electrical response can be positively correlated to the presence of a particular gas species in the MEMS gas sensor 700.

FIG. 13 is a flowchart illustrating one method 1300 of identifying the presence of a gas species of interest in the MEMS gas sensor 700 using the field effect transistor 1200 of FIG. 12. The method begins at a block 1302, in which the electrodes 716 are electrically connected to the field effect transistor 1200. The method next moves to a block 1304, in which a voltage V is applied between the absorber layer 704 and the electrodes 716.

Moving next to a block 1306, the time it takes for an electrical event to occur in the field effect transistor 1200 is electrically measured. In one embodiment, the time it takes for current to appear in the drain terminal 1230 of the field effect transistor 1200 is determined through electrical measurement at block 1306. In another embodiment, the time it takes to open the gate terminal 1210 of the field effect transistor 1200 is determined through electrical measurement at block 1306.

In some embodiments, the blocks 1302, 1304, and 1306 are performed at block 1108 of FIG. 11, in which the electrical response of the gas sensor 700 is measured after it has been exposed to a gas species of interest. Persons of skill in the art will also understand that, in other embodiments, the blocks 1302, 1304, and 1306 are performed at block 1102 of FIG. 11, in which the MEMS gas sensor 700 is calibrated in the absence of a gas species of interest. For example, the time it takes for current to appear in the drain terminal 1230 (or, alternatively, the time it takes to open the gate terminal 1210) can be measured in the absence of a gas during a calibration procedure performed during manufacture of the MEMS gas sensor 700. Some time later, after exposure to a gas species of interest and heating of the sensor layer 710, the time for current to appear in the drain terminal 1230 (or, alternatively, the time to open the gate terminal 1210) can be measured a second time in order to detect the presence of the gas.

The method next moves to a block 1308, in which the electrical response determined at block 1306 is compared to the electrical response the MEMS gas sensor 700 would be expected to exhibit in the absence of the gas species of interest. In some aspects, a calibration procedure performed at block 1102 of FIG. 11 provides information on the anticipated electrical response of the MEMS gas sensor 700 in the absence of the gas species of interest. For example, in one embodiment, the time it takes for current to appear in the drain terminal 1230 in the absence of the gas is compared at block 1308 to the time measured at block 1306.

In another embodiment the time it takes for current to appear in the drain terminal 1230 in the absence of the gas is estimated based on known electrical and material property characteristics of MEMS gas sensors 700 at a specific temperature. For example, the time it takes for current to appear in the drain terminal of multiple MEMS gas sensors 700, operating at a particular temperature in the absence of a gas, can be tested. The anticipated time for current to appear in the drain terminal of a specific MEMS gas sensor 700, operating at the same temperature in the absence of a gas, can be estimated based on the test data. In this embodiment, the anticipated time is compared to the time it actually took current to appear in the drain terminal 1230 as measured at block 1306 at block 1308.

It will also be understood that, alternatively, the time it takes to open the gate terminal 1210 of the field effect transistor can be used to compare a determined electrical response to an anticipated electrical response in the absence of the gas species of interest.

Moving next to a block 1310, the presence of the gas species of interest is identified. In one embodiment, the difference between the electrical response of the gas sensor 700 (determined at block 1306 by, for example, measuring the time for current to appear in the drain terminal 1230) and the anticipated electrical response of the gas sensor 700 (determined, for example, during calibration at block 1102 of FIG. 11) is correlated to the presence of a gas species of interest in the gas sensor 700. In another embodiment, the specific electrical response of the MEMS gas sensor 700 in the presence of a gas is used to determine the concentration of the gas species.

Some time after exposure to the gas species of interest, the residual stress of the sensing layer 710 may return to that which the sensing layer 710 exhibited before exposure to the gas. Thus, in some embodiments, the change in capacitance in the one or more layers of the MEMS gas sensor 700 described above is reversible and nonpermanent. In one embodiment, the MEMS gas sensor 700 is reusable and can detect the presence of a gas species of interest one or more times over the lifetime of the MEMS gas sensor 700.

### Determining Capacitance Change by Measuring Actuation Time

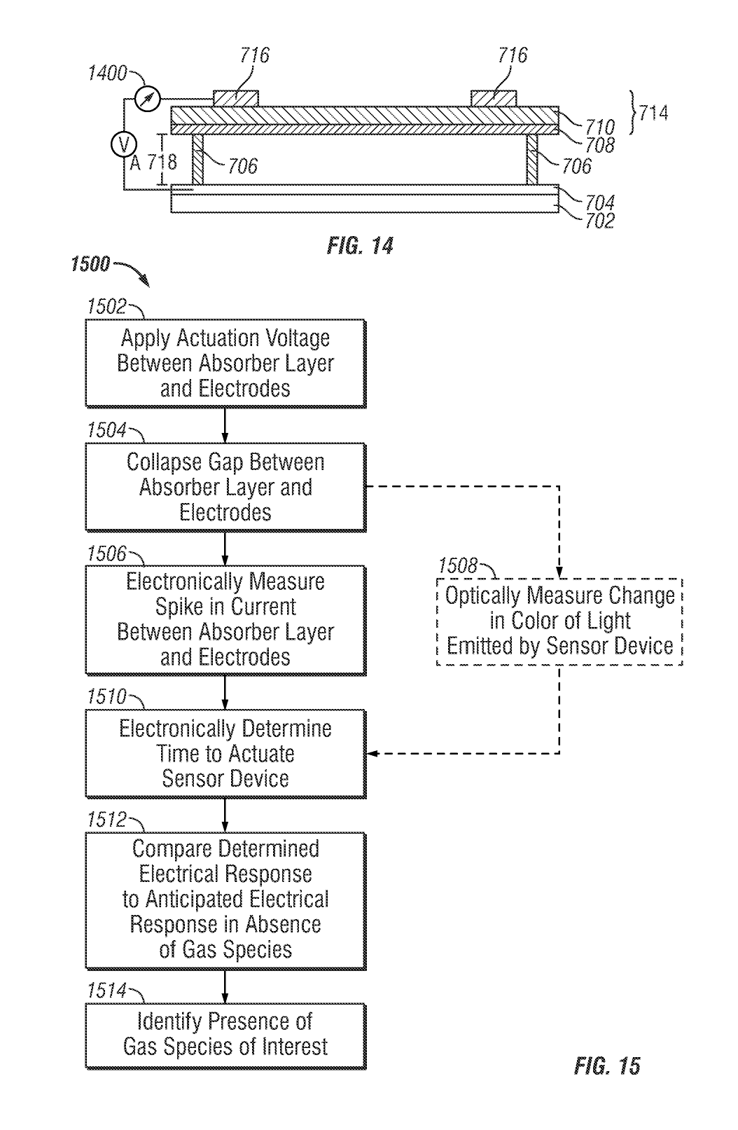

FIG. 14 is a cross section of the MEMS gas sensor 700 connected to an ammeter 1400. The ammeter 1400 measures the electric current in the circuit formed between the absorber layer 704 and the electrodes 716 when a voltage V is applied between the absorber layer 704 and the electrodes 716.

As described above with reference to FIGS. 12-13, the presence of a gas in the MEMS gas sensor 700 can change the capacitances between various components of the sensor 700. This change in capacitance can be determined or detected as a change in the electrical response of the MEMS gas sensor 700. In one embodiment illustrated in FIG. 14, the change in electrical response of the MEMS gas sensor 700 is a change in the time it takes to actuate the MEMS gas sensor 700. This change in actuation time can be positively correlated to the presence of a particular gas species in the MEMS gas sensor 700.

FIG. 15 is a flowchart illustrating one method of identifying the presence of a gas species of interest using the ammeter 1400 of FIG. 14 or a spectrometer (not shown) to determine a change in the actuation time of the MEMS gas sensor 700. The method begins at a block 1502, in which a selected voltage, for example an actuation voltage V_{A}, is applied between the absorber layer 704 and the electrodes 716. This causes the movable element 714 of the MEMS gas sensor 700 to move toward the absorber layer 704. Thus, in certain embodiments, the distance between the movable element 714 and the absorber layer 704 is a function of a voltage applied between the movable element 714 and the absorber layer 704.

Moving next to a block 1504, the gap 718 between the absorber layer 704 and the movable element 714 is collapsed in response to the actuation voltage. Methods and systems for actuating the MEMS gas sensor 700 are described in greater detail above with reference to FIG. 1, and in particular the actuated pixel 12b on the right in FIG. 1. When the MEMS gas sensor 700 is actuated and the gap 718 is collapsed, current in the circuit between the absorber layer 704 and the electrodes 716 will increase or spike. In addition, as described in detail above with reference to FIG. 7A, one or more properties of light emitted from the sensor 700 can be modulated when the sensor 700 is actuated and the movable element 714 moves toward the substrate 702. In one embodiment, the color of light emitted by the MEMS gas sensor 700 changes when the sensor 700 is actuated and the gap 718 is collapsed. The spike in current in the circuit and/or the change in the color of light emitted by the sensor 700 can be indicative that the MEMS gas sensor 700 has been actuated and the gap 718 has collapsed.

At a block 1506, the increase or spike in current in the circuit between the absorber layer 704 and the electrodes 716 is electronically measured using the ammeter 1400 connected to the MEMS gas sensor 700.

The method may alternatively move to a block 1508 from block 1504. At block 1508, the color of light emitted by the MEMS gas sensor 700 is optically measured in order to detect a change in the color of light emitted by the sensor 700. In one embodiment, detecting a change in the color of light comprises using a spectrometer (not shown) to optically detect a change in the color of light emitted by the MEMS gas sensor 700.

Moving next to a block 1510, the time to actuate the MEMS gas sensor 700 is electronically determined. In one embodiment, the actuation time is determined at block 1510 using information gathered at block 1506 when the spike in current in the circuit between the absorber layer 704 and the electrodes 716 was measured electronically. In another embodiment, the actuation time is determined at block 1510 using information gathered at block 1508 when a change in the color of light emitted by the MEMS gas sensor 700 was determined optically.

At a block 1512, the electrical response (in this case, the actuation time) determined at block 1510 is compared to the electrical response the MEMS gas sensor 700 would be expected to exhibit in the absence of the gas species of interest. In some aspects, a calibration procedure performed at block 1102 of FIG. 11 provides information on the anticipated electrical response of the MEMS gas sensor 700 in the absence of the gas species of interest. For example, in one embodiment, the actuation time of the sensor 700 in the absence of the gas is compared at block 1512 to the actuation time determined at block 1510.

In another embodiment, the actuation time of the sensor 700 in the absence of the gas is estimated based on known electrical and material property characteristics of MEMS gas sensors 700 at a specific temperature. For example, the actuation time of multiple MEMS gas sensors 700 operating at a particular temperature, in the absence of a gas, can be tested. The anticipated actuation time of a specific MEMS gas sensor 700, operating at the same temperature in the absence of a gas, can be estimated based on the test data. In this embodiment, this anticipated actuation time is compared to the actual actuation time determined at block 1510 at block 1512.

Moving next to a block 1514, the presence of the gas species of interest is identified. In one embodiment, the difference between the electrical response of the gas sensor 700 (determined at block 1510 by, for example, determining its actuation time) and the anticipated electrical response of the gas sensor 700 (determined, for example, during calibration at block 1102 of FIG. 11) is correlated to the presence of a gas species of interest in the gas sensor 700. In another embodiment, the specific electrical response of the MEMS gas sensor 700 in the presence of a gas is used to determine the concentration of the gas species.

### Packaging

Embodiments of gas sensors described herein can be packaged using various methods and systems. For example, in one aspect, the MEMS gas sensor 700 is packaged in a device that is chosen or selected based on the anticipated environment the MEMS gas sensor 700 will operate in. It can be anticipated, for example, that the MEMS gas sensor 700 will operate in an environment where the presence of CO₂ gas is of interest. The MEMS gas sensor 700 can be packaged in a device configured to facilitate detection of the gas species of interest, in this case CO₂, by the gas sensor 700.

In some aspects, the MEMS gas sensor 700 is enclosed in a package comprising epoxy and a piece of glass or film. For example, the piece of glass and/or film can be coupled to the substrate 702 of the gas sensor 700 using epoxy to form a package around the gas sensor 700. In one embodiment, the epoxy used to seal and/or form the package is permeable to a particular gas species of interest, for example CO₂. It will also be understood that embodiments of the gas sensors described herein do not require packaging and can be integrated into display devices or any other device without the use of a package.

In certain embodiments, the change in capacitance in the layers of the MEMS gas sensors described herein is reversible and non-permanent. Thus, in one embodiment, a non-permanent electrical and/or mechanical response occurs in the MEMS gas sensor 700 as a result of the presence of a gas species of interest in the MEMS gas sensor 700. After a time, the MEMS gas sensor 700 returns to its original electrical and/or mechanical state prior to exposure to the gas species of interest. Thus, embodiments of the MEMS gas sensor devices described herein can be used repeatedly to detect a gas species of interest. It will be understood that in other embodiments, the capacitance change in the layers of the MEMS gas sensors described herein can be permanent and nonreversible.

The skilled artisan will understand that the gas sensing methods and systems described herein are not limited to MEMS devices. The methods and systems described herein can be used in any display device requiring a gas sensor, such as OLED or LCD devices. It will also be understood that use of the gas sensors described herein are not limited to display devices, and can be used in any environment in which detection of a particular gas species of interest is required.

One of skill in the art will also understand that embodiments of gas sensors described herein can be included in a variety of displays, such as but not limited to MEMS, LCD, and AMOLED displays. One or more MEMS gas sensors can be fabricated during the manufacture of the display. In one embodiment, the MEMS gas sensor 700 is fabricated on the periphery of an active area of a display. In another embodiment, the MEMS gas sensor 700 is fabricated in place of a sub-pixel in the display. In some aspects, the MEMS gas sensor 700 which has been fabricated in place of a sub-pixel is located in the active area of the display, yet is not visible to the human eye. It will also be understood that one display can include a plurality of MEMS gas sensors 700, some located in the periphery of the active area of the display and others located in the active area of the display.

The hardware and data processing apparatus used to implement the various illustrative logics, logical blocks, modules and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

Various modifications to the implementations described in this disclosure may be readily apparent to those skilled in the art, and the generic principles defined herein may be applied to other implementations without departing from the spirit or scope of this disclosure. Thus, the present disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of sensing a chemical, comprising:
determining a capacitance change between at least two layers in a microelectromechanical system (MEMS) device, the capacitance between the at least two layers indicative of a presence of one or more chemicals; and
identifying the presence of the one or more chemicals based on a determined electrical response of the at least two layers and the determined capacitance change.

2. The method of claim 1, wherein determining a capacitance change comprises determining an actuation time of the MEMS device in response to a selected voltage.

3. The method of claim 2, wherein determining an actuation time comprises electronically measuring a change in current.

4. The method of claim 2, wherein determining an actuation time comprises optically measuring a change in a gap distance between the at least two layers.

5. The method of claim 4, wherein optically measuring a change in the gap distance comprises detecting a change in the color of light emitted by the MEMS device.

6. The method of claim 1, wherein determining a capacitance change comprises determining the voltage required to collapse the MEMS device.

7. The method of claim 1, wherein determining a capacitance change comprises determining a time to open a gate of a field effect transistor.

8. The method of claim 1, wherein the change in capacitance between the at least two layers is a function of a change in residual stress in a sensing layer in the MEMS device.

9. The method of claim 8, wherein the change in residual stress of the sensing layer is a function of the presence of the one or more chemicals.

10. A sensor comprising:
a movable layer configured to react to at least one chemical; and
a second layer spaced from the movable layer,
wherein a change in capacitance between the movable layer and the second layer and a determined electrical response resulting from the change in capacitance are indicative of the presence of the at least one chemical.

11. The sensor of claim 10, wherein a distance between the movable layer and the second layer is a function of the presence of the at least one chemical.

12. The sensor of claim 10, wherein the movable layer comprises a sensing layer that has a residual stress that is a function of the presence of the at least one chemical.

13. The sensor of claim 12, wherein the movable layer comprises a heating layer configured to heat the sensing layer.

14. The sensor of claim 10, wherein a distance between the movable layer and the second layer is a function of a voltage applied between the movable layer and the second layer.

15. The sensor of claim 12, wherein the sensing layer comprises a metal oxide.

16. The sensor of claim 13, wherein the heating layer comprises indium tin oxide.

17. The sensor of claim 14, wherein the movable layer comprises aluminum or platinum.

18. The sensor of claim 10, wherein the change in capacitance between the movable layer and the second layer is reversible.

19. The sensor of claim 10, further comprising a substrate spaced from the second layer such that the second layer is disposed between the substrate and the movable layer.

20. The sensor of claim 19, wherein the substrate comprises glass.

21. The sensor of claim 10, wherein the sensor comprises an interferometric modulator.

22. The sensor of claim 10, further comprising:
a display;
a processor that is configured to communicate with the display, the processor being configured to process image data; and
a memory device that is configured to communicate with the processor.

23. The sensor of claim 22, further comprising:
a driver circuit configured to send at least one signal to the display.

24. The sensor of claim 23, further comprising:
a controller configured to send at least a portion of the image data to the driver circuit.

25. The sensor of claim 22, further comprising:
an image source module configured to send the image data to the processor.

26. The sensor of claim 25, wherein the image source module comprises at least one of a receiver, transceiver, and transmitter.

27. The sensor of claim 22, further comprising:
an input device configured to receive input data and to communicate the input data to the processor.

28. A sensor comprising:
means for sensing at least one chemical; and
a layer spaced from the sensing means,
wherein a change in capacitance between the sensing means and the layer and a determined electrical response resulting from the change in capacitance are indicative of the presence of the at least one chemical.

29. The sensor of claim 28, wherein the sensing means comprises a movable layer configured to react to at least one chemical.

30. The sensor of claim 28, wherein the sensor comprises means for interferometrically modulating light.
